(19) United States
(12) Patent Application Publication
(10) Pub. No.: US 2015/0318150 A1
(43) Pub. Date: Nov. 5, 2015

(54) REAL-TIME EDGE ENCROACHMENT CONTROL FOR WAFER BEVEL

(71) Applicant: Lam Research Corporation, Fremont, CA (US)

(72) Inventor: Andreas Fischer, Castro Valley, CA (US)

(73) Assignee: Lam Research Corporation, Fremont, CA (US)

(21) Appl. No.: 14/266,575

(22) Filed: Apr. 30, 2014

(51) Int. Cl. H01J 37/32; H01L 21/02; H01L 21/67; H01L 21/3065

(52) U.S. Cl. CPC H01J 37/32385; H01J 37/32926; H01J 37/32155; H01J 37/32642; H01J 37/32183; H01L 21/3065; H01L 21/02021; H01L 21/67069

(57) ABSTRACT

A plasma processing system includes a bottom electrode disposed in a chamber. A lower extended electrode is disposed around the bottom electrode. An upper ceramic plate is disposed above the bottom electrode in an opposing relationship. An upper extended electrode is disposed around the upper ceramic plate. A lower process exclusion zone (PEZ) ring is situated between the lower extended electrode and the bottom electrode. An upper PEZ ring is situated between the upper extended electrode and the upper ceramic plate, with the upper PEZ ring having an RF electrode ring embedded therein. The system also includes a first RF generator for generating RF power for the bottom electrode, a second RF generator for generating RF power for the RF electrode ring embedded in the upper PEZ ring, and a controller for transmitting processing instructions. The processing instructions include power settings for the first and second RF generators.

### BACKGROUND

In semiconductor fabrication, film build up can occur at the bevel edge of a wafer during the fabrication process. Excess film at the bevel edge of a wafer is susceptible to flaking, e.g., during wafer transport. If flakes from the bevel edge of a wafer come into contact with a wafer (either the same wafer or a different wafer), the wafer is contaminated and defects can result. To prevent flaking from occurring, bevel edge etching is performed to remove the film build up.

In current bevel edge etching processes, the encroachment profile of plasma at the wafer bevel is controlled using a set of process exclusion zone (PEZ) rings that includes an upper PEZ ring and a lower PEZ ring. The outer diameter of the upper and lower PEZ rings has a profound effect on the encroachment profile of plasma at the upper and lower wafer bevels, and this profile determines the distance from the wafer apex at which the film build up is removed. Thus, to achieve different encroachment profiles to meet the needs of chip manufacturers, different sets of PEZ rings having different outer diameters must be used.

Having to use a different set of PEZ rings (with a different outer diameter) to achieve a different encroachment profile in bevel edge etching is time consuming because it involves replacing parts in the chamber. Moreover, it requires breaking the vacuum in the chamber and thereby incurs the risk that the chamber will become contaminated. The use of different sets of PEZ rings is also costly as it requires suppliers to carry PEZ rings having multiple sizes in inventory rather than PEZ rings having just one size.

It is in this context that embodiments arise.

### SUMMARY

In an example embodiment, a plasma processing system includes a chamber and a bottom electrode disposed in the chamber. A lower extended electrode is disposed around the bottom electrode. An upper ceramic plate is disposed in the chamber, with the upper ceramic plate being disposed above the bottom electrode in an opposing relationship with the bottom electrode, such that, when a wafer is present over the bottom electrode, a separation gap is defined between a top surface of the wafer and the upper ceramic plate, with the separation gap being less than about 2.0 mm. An upper extended electrode is disposed around the upper ceramic plate. A lower process exclusion zone (PEZ) ring is situated between the lower extended electrode and the bottom electrode. An upper process exclusion zone (PEZ) ring is situated between the upper extended electrode and the upper ceramic plate, with the upper PEZ ring having a radio frequency (RF) electrode ring embedded therein. The plasma processing system also includes a first RF generator for generating RF power for the bottom electrode, a second RF generator for generating RF power for the RF electrode ring embedded in the upper PEZ ring, and a controller for transmitting processing instructions. The processing instructions include, among other settings, a power setting for the first RF generator and a power setting for the second RF generator.

In one embodiment, the power setting for the second RF generator is lower than the power setting for the first RF generator. In one embodiment, a cooling plate is disposed over the upper ceramic plate, the upper PEZ ring, and the upper extended electrode, and the power generated by the second RF generator is communicated to the embedded RF electrode ring via an RF feed rod that passes through the cooling plate.

In one embodiment, the lower PEZ ring is comprised of an insulative material that electrically separates the bottom electrode from the lower extended electrode. In one embodiment, the upper PEZ ring is comprised of an insulative material that electrically separates the embedded RF electrode ring from the upper extended electrode.

In one embodiment, the upper PEZ ring has a side surface that defines an outer circumference of the upper PEZ ring and a lower surface that defines a base of the upper PEZ ring. The RF electrode ring is embedded within the upper PEZ ring so that a side surface of the RF electrode ring is proximate to the side surface of the upper PEZ ring and a bottom surface of the RF electrode ring is proximate to the lower surface of the upper PEZ ring.

In one embodiment, the RF electrode ring is embedded within the upper PEZ ring so that the side surface of the RF electrode ring is within about 1.0 mm of the side surface of the upper PEZ ring and the bottom surface of the RF electrode ring is within about 1.0 mm of the lower surface of the upper PEZ ring.

In another example embodiment, a method includes generating a plasma for bevel edge processing of a wafer when present, the plasma being generated using radio frequency (RF) power delivered to the main electrode supporting the wafer. The RF power may be generated by a main RF generator. The method includes providing an upper PEZ ring that defines a physical boundary that establishes an amount of encroachment of the plasma toward a center of the wafer from a bevel edge process region. The method also includes applying RF power to an electrode in the upper PEZ ring. The RF power applied to the electrode in the upper PEZ ring is generated by a secondary RF generator that is separate from the main RF generator. The method further includes controlling the RF power applied to the electrode in the upper PEZ ring to provide an additional barrier to plasma to reduce the amount of encroachment of the plasma toward the center of the wafer from the bevel edge process region. The reduction in the amount of encroachment of the plasma causes less of the periphery of the wafer to be bevel edge processed with the generated plasma.

In one embodiment, the RF power applied to the electrode in the upper PEZ ring is applied at a low frequency. In one embodiment, the low-frequency RF power applied to the electrode in the upper PEZ ring is applied at a relatively low power level that does not exceed approximately 200 watts, such that the low-frequency RF power produces an electric field in and around the upper PEZ ring that exerts a force against the generated plasma for bevel edge processing that causes the generated plasma to be forced away from the center of the wafer, thereby increasing the plasma sheath. The setting of increased power settings from zero watts to approximately 200 watts respectively increases an amount of force the electric field exerts against the generated plasma and thereby reduces the amount of the periphery of the wafer that is bevel edge processed with the generated plasma. In one embodiment, the RF power applied to the electrode in the upper PEZ ring is applied at a low frequency of approximately 400 kHz.

In one embodiment, the controlling of the RF power applied to the electrode in the upper PEZ ring to provide an additional barrier to plasma to reduce the amount of encroachment of the plasma toward the center of the wafer from the bevel edge process region includes two operations. The first operation includes identifying a range of RF power levels that cause the amount of encroachment of the plasma toward the center of the wafer from the bevel edge process region to vary between a maximum amount of encroachment and a minimum amount of encroachment. The second operation includes adjusting the RF power level to a power level within the range of identified RF power levels to obtain a selected amount of encroachment of the plasma.

In yet another example embodiment, a plasma processing system includes a chamber and a bottom electrode disposed in the chamber. A lower extended electrode is disposed around the bottom electrode. An upper ceramic plate is disposed in the chamber, with the upper ceramic plate being disposed above the bottom electrode in an opposing relationship with the bottom electrode, such that a separation gap is defined between a top surface of a wafer, when present over the bottom electrode, and the lower surface of the upper ceramic plate, with the separation gap being less than about 2.0 mm. An upper extended electrode is disposed around the upper ceramic plate. A lower PEZ ring is situated between the lower extended electrode and the bottom electrode. The lower PEZ is comprised of an insulative material that electrically separates the bottom electrode from the lower extended electrode. An upper PEZ ring is situated between the upper extended electrode and the upper ceramic plate. The upper process exclusion zone ring has an RF electrode ring embedded therein. The upper PEZ ring is comprised of an insulative material that electrically separates the embedded RF electrode ring from the upper extended electrode. The plasma processing system also includes an RF generator for generating RF power for the bottom electrode, and an encroachment power module. The RF generator for generating the RF power for the bottom electrode has a matching circuit associated therewith. The encroachment power module includes an RF generator for generating RF power for the RF electrode ring embedded in the upper PEZ ring, and a matching circuit associated with the RF generator for generating the RF power for the RF electrode ring embedded in the upper PEZ ring. The plasma processing system further includes a controller for transmitting processing instructions. The processing instructions include general etch settings and encroachment control settings.

In one embodiment, the encroachment control settings include a power setting for the RF generator included in the encroachment power module. In one embodiment, the power setting for the RF generator included in the encroachment power module is lower than the power setting for the RF generator for generating the RF power for the bottom electrode.

In one embodiment, the power setting for the RF generator included in the encroachment power module does not exceed approximately 200 watts. In one embodiment, the RF power generated by the RF generator included in the encroachment power module is low frequency power. In one embodiment, the low-frequency RF power has a frequency of approximately 400 kHz.

Other aspects and advantages of the disclosures herein will become apparent from the following detailed description, taken in conjunction with the accompanying drawings, which illustrate by way of example the principles of the disclosures.

### BRIEF DESCRIPTION OF THE DRAWINGS

FIG. 1A is a schematic diagram of a plasma processing system, in accordance with an example embodiment.

FIG. 1B is a schematic diagram that shows additional details of a plasma processing system, in accordance with an example embodiment.

FIG. 2A is a schematic diagram that illustrates a top view of the upper process exclusion zone (PEZ) ring and the embedded RF electrode, in accordance with an example embodiment.

FIG. 2B is a schematic diagram that illustrates a top view of the upper process exclusion zone (PEZ) ring and the embedded RF electrode, in accordance with another example embodiment.

FIG. 3A is a schematic diagram that illustrates a cross-sectional view of bevel edge processing in a case in which the RF generator is turned off so that RF power is not being provided to the embedded RF electrode, in accordance with an example embodiment.

FIG. 3B is a schematic diagram that illustrates a cross-sectional view of bevel edge processing in a case in which the RF generator providing RF power to the embedded RF electrode is at a first power level, in accordance with an example embodiment.

FIG. 3C is a schematic diagram that illustrates a cross-sectional view of bevel edge processing in which the RF generator providing RF power to the embedded RF electrode is at a second power level, in accordance with an example embodiment.

FIG. 3D is a schematic diagram that illustrates a cross-sectional view of bevel edge processing in which the RF generator providing RF power to the embedded RF electrode is at a third power level, in accordance with an example embodiment.

FIG. 4 is a flowchart diagram illustrating the method operations performed in the bevel edge processing of a wafer, in accordance with an example embodiment.

### DETAILED DESCRIPTION

In the following description, numerous specific details are set forth in order to provide a thorough understanding of the example embodiments. However, it will be apparent to one skilled in the art that the example embodiments may be practiced without some of these specific details. In other instances, process operations and implementation details have not been described in detail, if already well known.

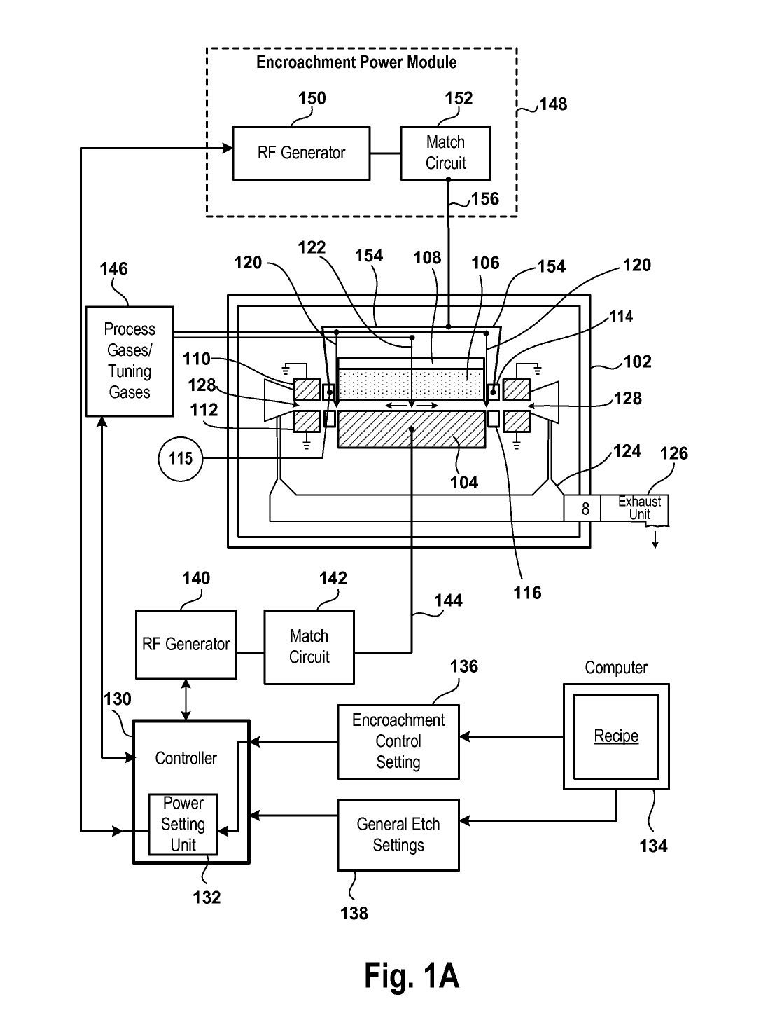

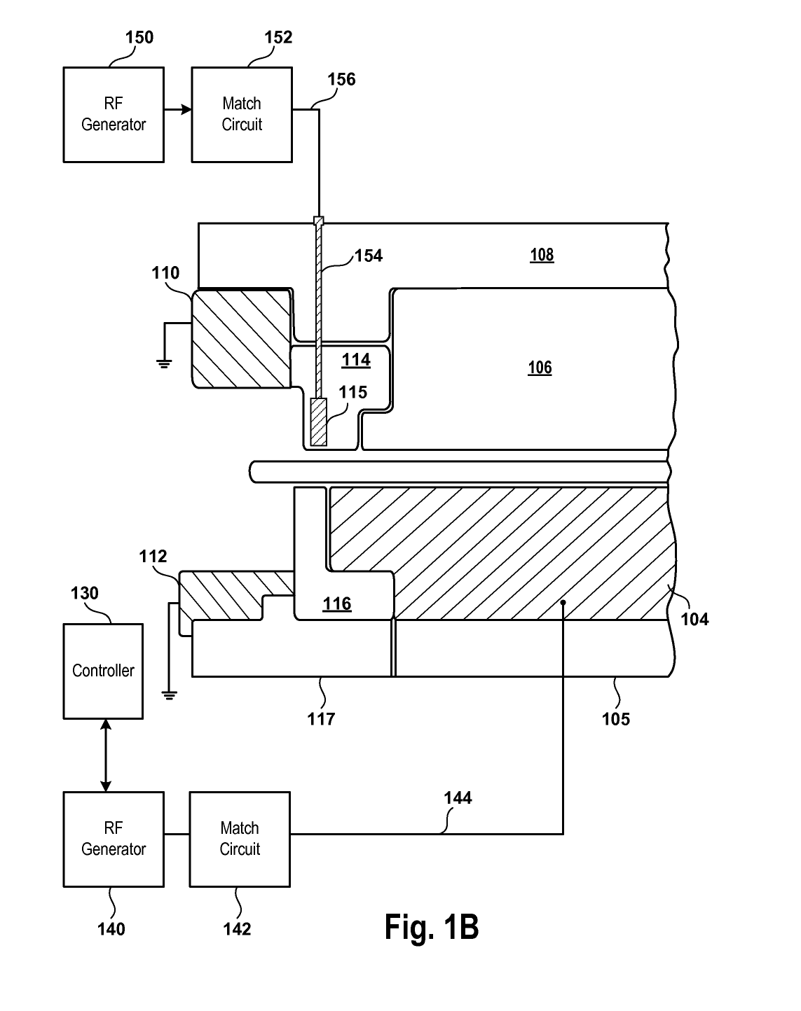

FIG. 1A is a schematic diagram of a plasma processing system, in accordance with an example embodiment. As shown in FIG. 1A, plasma processing system 100 includes a chamber 102 in which a bottom electrode 104 is disposed. In one example, the bottom electrode 104 is formed of anodized aluminum. The bottom electrode 104 provides support for a wafer during plasma processing. During plasma processing, bottom electrode 104 is cooled with a chiller to a set temperature. In one example, the chiller cools the bottom electrode to ambient temperature (e.g., about 20 degrees Celsius). In another example, the chiller cools the bottom electrode to a temperature in the range from about 10 degrees Celsius to about 60 degrees Celsius. Upper ceramic plate 106 is disposed above bottom electrode 104 so that when a wafer is supported on the bottom electrode there is only a narrow gap above the top surface of the wafer, as described in more detail below with reference to FIG. 1B. Upper cooling plate 108 is situated above the upper ceramic plate 106. Upper extended electrode 110 is disposed around upper ceramic plate 106 and lower extended electrode 112 is disposed around bottom electrode 104. The lower extended electrode 112 and the bottom electrode 104 are situated such that there is sufficient space therebetween to avoid direct RF coupling of these electrodes. Upper extended electrode 110 and lower extended electrode 112, both of which are grounded, can be made of any suitable conductive material, e.g., anodized aluminum or yttria (Y₂O₃)-coated aluminum.

An upper process exclusion zone (PEZ) ring 114 is situated between upper ceramic plate 106 and upper extended electrode 110. A lower process exclusion zone (PEZ) ring 116 is situated between bottom electrode 104 and lower extended electrode 112. A radio frequency (RF) electrode 115 is embedded within upper PEZ ring 114. Both upper PEZ ring 114 and lower PEZ ring 116 can be made of any suitable insulative material, e.g., yttria (Y₂O₃). The insulative material used to form lower PEZ ring 116 electrically separates bottom electrode 104 and lower extended electrode 112 from each other. The insulative material used to form upper PEZ ring 114 physically separates the upper PEZ ring from the upper ceramic plate 106 and electrically separates the upper PEZ ring from the upper extended electrode 110. Of course, as will be appreciated by those skilled in the art, RF power can pass through insulative materials. Thus, by way of example, RF power can pass from bottom electrode 104 to lower extended electrode 112 through lower PEZ ring 116. Embedded RF electrode 115 can be made of any suitable metallic material, and is fully embedded within upper PEZ ring 114 to avoid introducing any metal contamination within chamber 102.

In one example, the RF electrode 115 is embedded within the upper PEZ ring 114 by machining an appropriately shaped opening (e.g., a cavity or pocket) in the upper PEZ ring and inserting the RF electrode into the opening. Once the RF electrode 115 has been inserted into the opening in the upper PEZ ring 114, a suitable top piece can be placed on the upper PEZ ring to cover the opening so that the RF electrode does not introduce any metal contamination within the chamber. It is noted that care should be taken when sizing the opening inside upper PEZ ring 114 in which RF electrode 115 is housed. No voids or gaps greater than about 0.5 mm should exist inside the opening to avoid plasma light up inside upper PEZ ring 114 around RF electrode 115. It will be appreciated by those skilled in the art that other techniques may be used to embed the RF electrode within the upper PEZ ring. By way of example, the upper PEZ ring may be formed by disposing the RF electrode within a mold, filling the mold with powdered material, compacting the powdered material (e.g., using an isostatic pressing technique), and subjecting the compacted material to any additional processing needed to bond the powder particles together (e.g., sintering).

With continuing reference to FIG. 1A, gas source 146 is coupled in flow communication with facilities that provide suitable process gases and tuning gases. Edge process gas delivery conduits 120 deliver process gas from gas source 146 to bevel edge process region 128 of chamber 102. Center gas delivery conduit 122 delivers process gas as well as tuning gas from gas source 146 to the center region of a wafer being processed in chamber 102. Exhaust manifold 124 collects gases to be exhausted from chamber 102 and directs such gases toward exhaust unit 126.

The recipe for a particular plasma processing operation can be input into computer 134. The recipe can include encroachment control settings 136 and general etch settings 138, both of which are transmitted from computer 134 to controller 130. Controller 130 communicates with RF generator 140, gas source 146, and encroachment power module 148 to implement the processing instructions set forth in the encroachment control settings 136 and the general etch settings 138. To implement the processing instructions set forth in the general etch settings 138, controller 130 transmits a power setting to RF generator 140 so that the RF generator can generate the appropriate RF power and transmit this power to bottom electrode 104 via RF feed rod 144. Matching circuit 142 is provided to reduce loss in the transmission of the RF power and thereby optimize delivery of the power, as is known to those skilled in the art. Controller 130 also transmits appropriate signal(s) to gas source 146 so that the needed processing gases and tuning gases can be delivered to chamber 102 via conduits 120 and 122. In one embodiment, controller 130 can be a computer or, more generally, a suitable computing device.

In one example, the general etch settings specify that the RF plasma for bevel edge processing is generated using a 13.56 MHz source and about 0.5 kilowatts of delivered power. In other examples, the power is in the range of from zero to about 1,000 watts, e.g., about 600 watts. In one example, the chamber is run at a pressure in the range of from about 1 Torr to about 10 Torr. In another example, the chamber is run at a pressure in the range from about 1 Torr to about 3 Torr, e.g. about 1.9 or 2.0 Torr.

To implement the processing instructions set forth in the encroachment control settings 136, power setting unit 132 of controller 130 transmits a power setting to encroachment power module 148, which includes RF generator 150 and matching circuit 152. RF generator 150 generates the appropriate RF power and transmits this power to embedded RF electrode 115 via RF conduit 156 and RF feed rods 154.

In one example, the encroachment control settings specify that the RF power transmitted to the embedded RF electrode is generated at a relatively low frequency and is applied at a relatively low power level. In one example, the relatively low frequency does not exceed about 400 kHz. In one example, the relatively low power level does not exceed about 200 watts, e.g., a power level in the range from zero watts to about 200 watts.

FIG. 1B is a schematic diagram that shows additional details of a plasma processing system, in accordance with an example embodiment. As shown in FIG. 1B, electrode support 105 provides support for bottom electrode 104. Lower isolation ring 117, which is disposed around electrode support 105, provides support for lower PEZ ring 116 and lower extended electrode 112. Upper cooling plate 108 is disposed above upper ceramic plate 106, upper PEZ ring 114, and upper extended electrode 110. The RF power generated by RF generator 150 is communicated through matching circuit 152 to the embedded RF electrode 115 via RF conduit 156 and RF feed rod 154. As shown in FIG. 1B, RF feed rod 154 passes through upper cooling plate 108 and upper PEZ ring 114 to embedded RF electrode 115. As the upper cooling plate 108 is a metal at ground potential, RF feed rod 154 should be provided with sufficient dielectric isolation to the upper cooling plate such that the amount of RF current that goes into ground is limited.

In one example, the top surface of lower PEZ ring 116 and the top surface of bottom electrode 104 are configured so that the top surface of the lower PEZ ring is slightly lower than the top surface of the bottom electrode. In one example implementation, the top surface of lower PEZ ring 116 is approximately 10 mils (10 thousandths of an inch) lower than the top surface of bottom electrode. In this manner, when a wafer is situated on the top surface of bottom electrode 104 for plasma processing, there is slight gap between the top surface of lower PEZ ring 116 and the lower surface of the wafer. In addition, the bottom electrode 104 and the upper ceramic plate 106 are spaced apart so that the separation gap between the top surface of the wafer and the lower surface of the upper ceramic plate is narrow enough to prevent plasma from advancing further toward the center of the wafer. In one example, the gap between the top surface of the wafer and the lower surface of the upper ceramic plate 106 is less than about 2.0 mm. In another example, the gap between the top surface of the wafer and the lower surface of the upper ceramic plate 106 is about 0.35 mm.

To facilitate the loading of a wafer into position for plasma processing, the upper ceramic plate 106 is movable between a process position and a wafer transport position. In the process position, as noted above, the separation gap between the top surface of the wafer and the lower surface of the upper ceramic plate 106 is less than about 2.0 mm. In the wafer transport position, the upper ceramic plate 106 is moved in an upward direction (relative to the bottom electrode 104) so that the gap between upper surface of the bottom electrode and the lower surface of the upper ceramic plate is at least about 20 mm. Those skilled in the art will appreciate that the size of the gap in the wafer transport position may be varied to suit the needs of the particular wafer transport equipment being used.

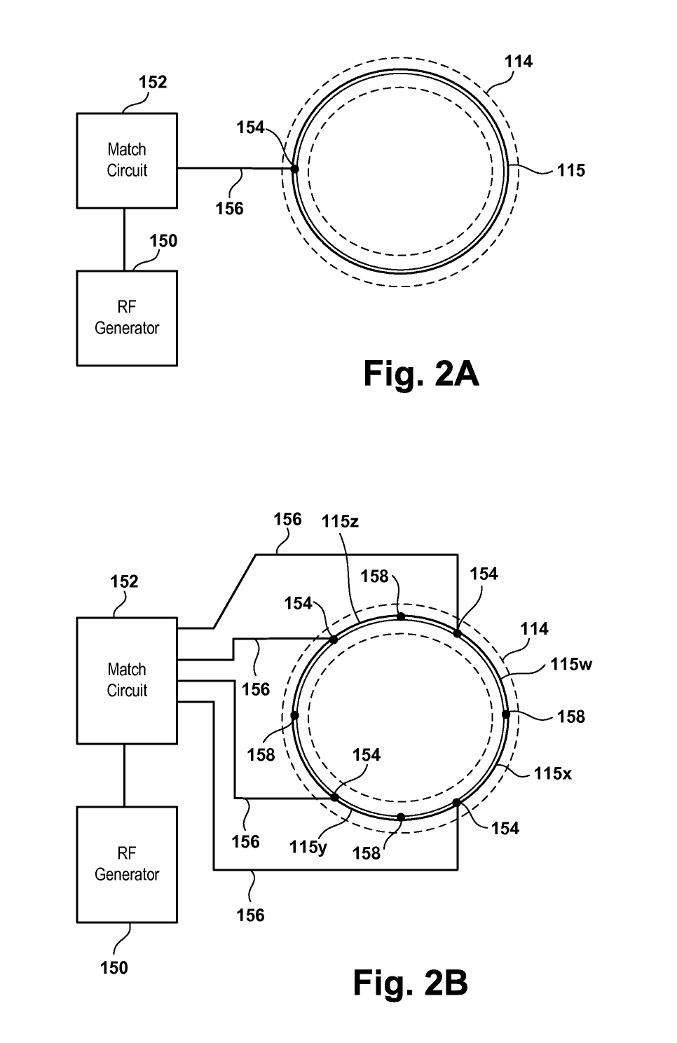

FIG. 2A is a schematic diagram that illustrates a top view of the upper PEZ ring and the embedded RF electrode, in accordance with an example embodiment. As shown in FIG. 2A, RF electrode 115 is embedded within upper PEZ ring 114 in the form of a single, continuous ring. The embedded RF electrode 115 receives the RF power from RF generator 150 via matching circuit 152, RF conduit 156, and RF feed rod 154. FIG. 2B is a schematic diagram that illustrates a top view of the upper PEZ ring and the embedded RF electrode, in accordance with another example embodiment. As shown in FIG. 2B, RF electrode 115 is embedded within upper PEZ ring 114 in the form of a ring that includes four curved segments 115w, 115x, 115y, and 115z, with each curved segment spanning an arc of approximately 90 degrees. Each of the segments of RF electrode 115 is separated from the adjacent segments by a segment insulator 158. Further, each of segments of RF electrode 115 receives the RF power from an RF feed rod 154 connected to that segment. Each of the RF feed rods 154 receives the RF power from an RF conduit 156 connected to that segment. Each of the RF conduits 156 is connected to matching circuit 152, which receives the RF power from RF generator 150. Those skilled in the art will appreciate that the number of segments used to form the embedded RF electrode 115 may be varied to meet the needs of particular applications.

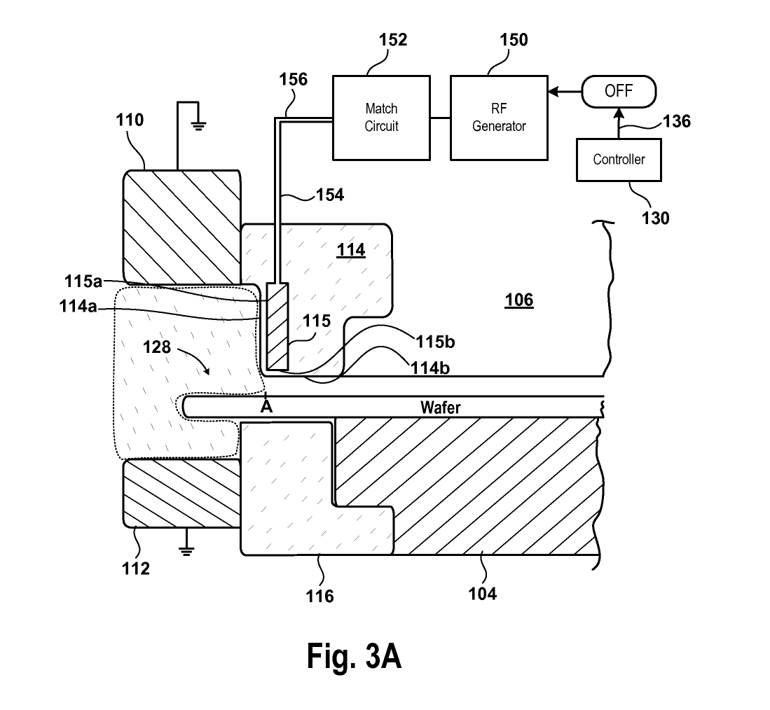

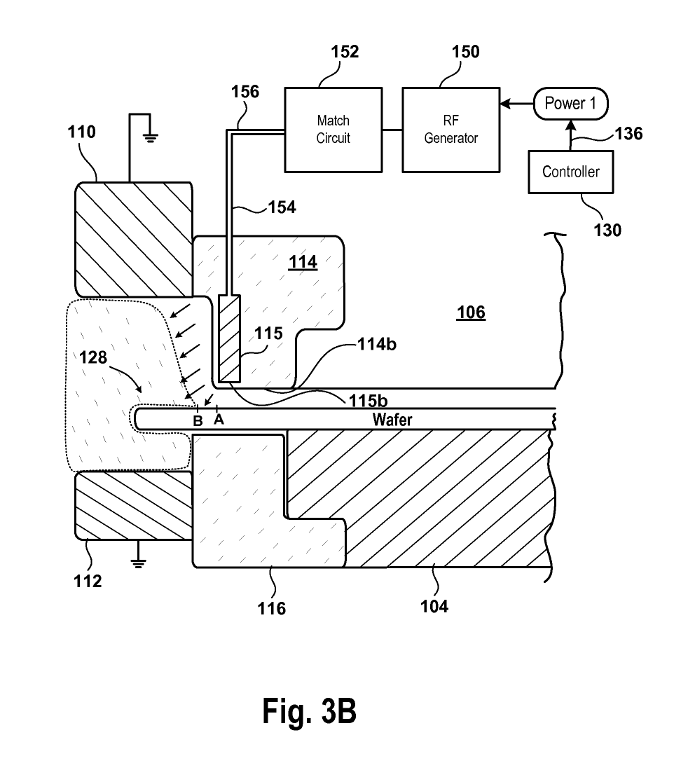

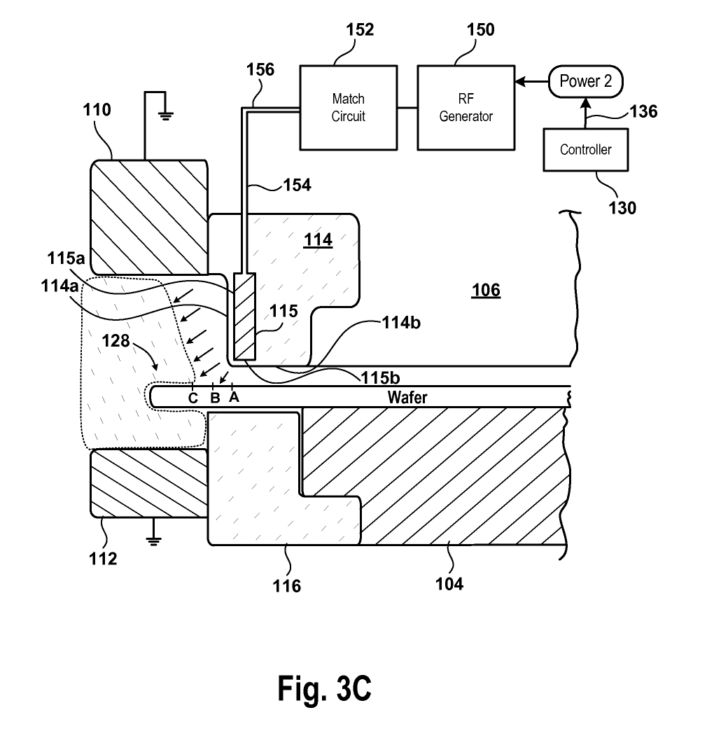

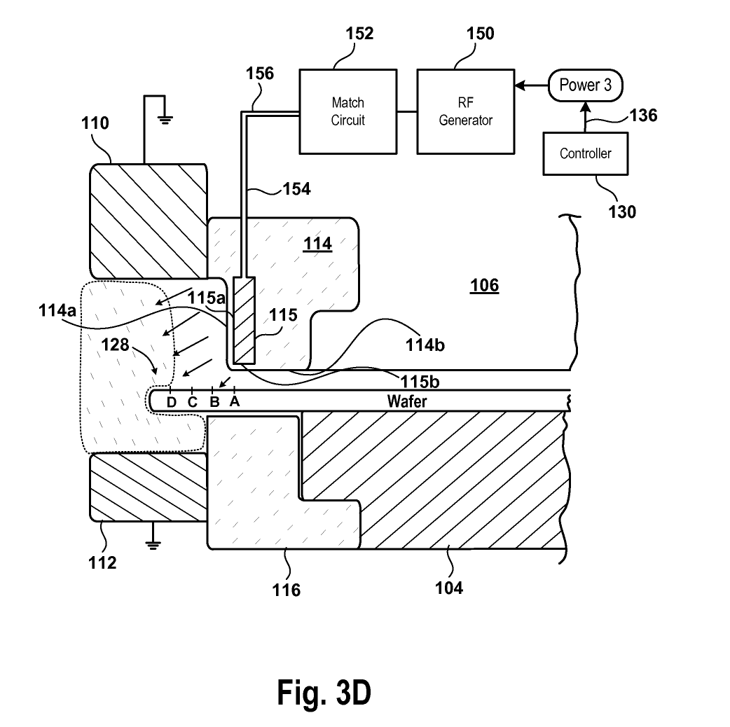

FIG. 3A is a schematic diagram that illustrates a cross-sectional view of bevel edge processing in a case in which the RF generator 150 is turned off so that RF power is not being provided to the embedded RF electrode, in accordance with an example embodiment. As shown in FIG. 3A, the plasma in bevel edge process region 128 is indicated by the light dotted line. As the RF generator 150 for embedded RF electrode 115 is turned off in this case, the embedded RF electrode is not receiving an RF power and therefore does not have any influence on the plasma. Consequently, the encroachment of the plasma toward the center of the wafer in this case is determined mainly by the outer diameter of the upper PEZ ring 114. Thus, the pinch-off point (the point at which substantially no etching occurs on the wafer) occurs near the point labeled “A,” the location of which corresponds to the outer diameter of the upper PEZ ring 114. Etching occurs on the periphery of the wafer, with the effectiveness of the etching being at a maximum near the edge of the wafer and gradually decreasing to a minimum at point A.

FIG. 3B is a schematic diagram that illustrates a cross-sectional view of bevel edge processing in a case in which the RF generator 150 providing RF power to the embedded RF electrode 115 is at a first power level, in accordance with an example embodiment. As shown in FIG. 3B, the plasma in bevel edge process region 128 has been pushed out toward the edge of the wafer so that the pinch-off point moves from point A to the point labeled “B.” Relative to point A (no RF power), point B is located closer to the edge of the wafer because the electric field generated by embedded RF electrode 115 has an influence on the charged species in the plasma and therefore acts as an additional barrier for plasma to enter the portion of bevel edge process region 128 that is directly above the wafer (and adjacent to the outer edge of upper PEZ ring 114). Consequently, the electric field exerts a force against the plasma that pushes the plasma away from the outer edge of upper PEZ ring 114 (compare FIG. 3B with FIG. 3A). The use of the lower frequency (e.g., 400 kHz) assures that no “new” plasma is formed next to the upper PEZ ring 114 when the embedded RF electrode 115 is powered. Rather the low frequency establishes an additional plasma sheath outside the PEZ ring which pushes the plasma further toward the edge of the wafer.

FIG. 3C is a schematic diagram that illustrates a cross-sectional view of bevel edge processing in which the RF generator 150 providing RF power to the embedded RF electrode 115 is at a second power level, in accordance with an example embodiment. As shown in FIG. 3C, the plasma in bevel edge process region 128 has been further pushed out toward the edge of the wafer so that the pinch-off point moves from point B to the point labeled “C.” Relative to point B (first power level), point C is located closer to the edge of the wafer because the second power level is higher than the first power level. The electric field generated by embedded RF electrode 115 at the second power lever has a greater influence on the charged species in the plasma than the electric field generated by the embedded RF electrode at the first power level. Consequently, the electric field generated by embedded electrode 115 at the second power level exerts a greater force against the plasma that pushes the plasma further away from the outer edge of upper PEZ ring 114 (compare FIG. 3C with FIG. 3B).

FIG. 3D is a schematic diagram that illustrates a cross-sectional view of bevel edge processing in which the RF generator providing RF power to the embedded RF electrode is at a third power level, in accordance with an example embodiment. As shown in FIG. 3D, the plasma in bevel edge process region 128 has been pushed out toward the edge of the wafer even further so that the pinch-off point moves from point C to the point labeled “D.” Relative to point C (second power level), point D is located closer to the edge of the wafer because the third power level is higher than the second power level. The electric field generated by embedded RF electrode 115 at the third power lever has a greater influence on the charged species in the plasma than the electric field generated by the embedded RF electrode at the second power level. Consequently, the electric field generated by embedded electrode 115 at the third power level exerts an even greater force against the plasma that pushes the plasma further away from the outer edge of upper PEZ ring 114 (compare FIG. 3D with FIG. 3C).

As shown in FIGS. 3A-3D, upper PEZ ring 114 has a side surface 114a that defines an outer circumference of the upper PEZ ring, and a lower surface 114b that defines a base of the upper PEZ ring. Further, embedded RF electrode 115 is embedded within the upper PEZ ring 114 so that side surface 115a of the embedded RF electrode is proximate to side surface 114a of the upper PEZ ring, and bottom surface 115b of the embedded RF electrode is proximate to lower surface 114b of the upper PEZ ring. In one example embodiment, the embedded RF electrode 115 is embedded within upper PEZ ring 114 such that side surface 115a is within about 1.0 mm of side surface 114a and bottom surface 115b is within about 1.0 mm of lower surface 114b. With the embedded RF electrode 115 positioned within a corner segment of upper PEZ ring 114 in this manner, the electric field produced by the embedded RF electrode can exert a force against the plasma sheath in the vicinity of side surface 114a as well as the plasma sheath in the vicinity of lower surface 114b of the upper PEZ ring.

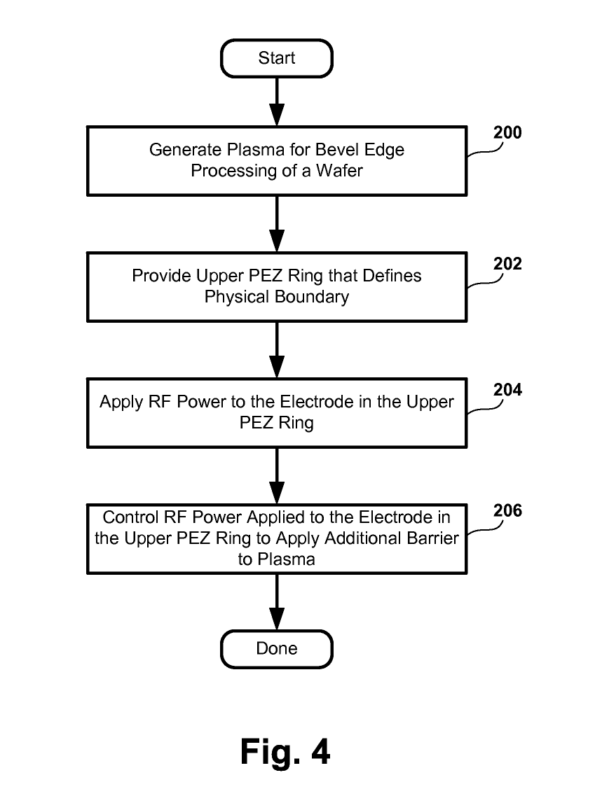

FIG. 4 is a flowchart diagram illustrating the method operations performed in the bevel edge processing of a wafer, in accordance with an example embodiment. In operation 200, a plasma for bevel edge processing of a wafer, when present, is generated using RF power delivered to the main electrode supporting the wafer. The RF power may be generated by a main RF generator. In one example implementation, the main RF generator uses 13.56 MHz. It will be appreciated by those skilled in the art that other frequencies also may be used, e.g., 2 MHz, 27 MHz, 60 MHz, etc. In operation 202, an upper PEZ ring is provided. The upper PEZ ring defines a physical boundary that establishes an amount of encroachment of the plasma toward a center of the wafer from a bevel edge process region. In one example implementation, the upper PEZ ring 114 shown in FIG. 3A is provided. The side surface 114a, which corresponds to the outer diameter of upper PEZ ring 114, defines the physical boundary that establishes the amount of encroachment of the plasma toward the center of a wafer from the bevel edge process region. In other words, the side surface 114a acts as a barrier that prevents encroachment of the plasma toward the center of the wafer.

In operation 204, RF power is applied to an electrode in the upper PEZ ring. The RF power may be generated by a secondary RF generator that is separate from the main RF generator. In the example implementation in which upper PEZ ring 114 shown in FIG. 3A is used, the RF power is provided to the RF electrode 115 embedded within the upper PEZ ring via RF generator 150 (see, for example, FIG. 3B). In one example, the secondary RF generator generates RF power at a relatively low frequency, e.g., a frequency that does not exceed about 400 kHz. In one example, the RF power applied to the RF electrode embedded in the upper PEZ ring is applied at a relatively low power level, e.g., a power level that does not exceed approximately 200 watts. As used herein, the terms “about” and “approximately” mean that the specified parameter can be varied within a reasonable tolerance, e.g., ±20%.

It will be appreciated by those skilled in the art that supplying RF power to the electrode in the upper PEZ ring may result in the generation of some “new” plasma (that is, generated plasma that either blends with or is combined with the plasma generated using the main RF generator) under the conditions typically found in bevel edge processing chambers. Thus, the parameters associated with the supply of RF power to the electrode (e.g., power level, frequency, etc.) should be selected to balance the need to generate an electric field that can sufficiently influence the plasma with the need to avoid generating a significant amount of new plasma (because the new plasma may reduce the ability to control plasma encroachment toward the center of wafer from the bevel edge process region). In general, however, even if new plasma is generated, using a low frequency, e.g., about 400 kHz, will ensure that new plasma generation can be reduced to a minimum. The use of a lower frequency ensures an enlargement of the plasma sheath outside the upper PEZ ring 114 consistent with a push out of the plasma toward the wafer edge.

In operation 206, the RF power applied to the electrode in the upper PEZ ring is controlled to provide an additional barrier to plasma to reduce the amount of encroachment of the plasma toward the center of the wafer from the bevel edge process region. In the example implementation in which the RF power is applied at a power level that does not exceed approximately 200 watts, the RF power is controlled by increasing the power setting from zero watts to approximately 200 watts. At a power level of zero watts, no electric field is generated (see FIG. 3A) and the physical boundary corresponds to the surface of the upper PEZ ring that defines the outer diameter of the upper PEZ ring. As the power level is increased, the force that the electric field produced in and around the upper PEZ ring exerts against the plasma increases. Thus, as the power level is increased, the degree to which the plasma is forced away from the center of the wafer (thereby increasing the sheath) increases (compare FIGS. 3B, 3C, and 3D). As a result, the amount of the periphery of the wafer that is bevel edge processed with the generated plasma is reduced as the power level is increased.

In the foregoing example implementation, the identified range of RF power levels extends from zero watts to approximately 200 watts. At a power level of zero watts, the amount of encroachment by the plasma toward the center of the wafer is at a relative maximum because the physical boundary for preventing encroachment corresponds to the outer diameter of the upper PEZ ring. At a power level of approximately 200 watts, the amount of encroachment by the plasma is at a relative minimum because the electric field exerts a greater force against the plasma. As such, the distance by which the plasma is forced away from the center of the wafer is the longest at the highest power level in the range. Thus, by increasing the power level to provide an additional barrier to the plasma, the physical boundary for preventing encroachment of the plasma is essentially “extended” from the surface that defines the outer diameter of the upper PEZ ring to a location that is farther away from the center of the wafer. In this manner, the amount of encroachment of the plasma toward the center of the wafer is adjusted without changing the physical size of the upper PEZ ring. This provides continuous, real-time control of the etching plasma during bevel edge plasma processing.

In an example implementation, the outer periphery of a wafer that is subjected to bevel edge processing includes a region that is within about 0.5 mm to about 5 mm from the edge of the wafer. In another example, the outer periphery of a wafer that is subjected to bevel edge processing includes a region that is within about 1.0 mm to about 3 mm from the edge of the wafer. In yet another example, the outer periphery of a wafer that is subjected to bevel edge processing includes a region that is within about 2.0 mm to about 2.5 mm from the edge of the wafer. The foregoing ranges for the outer periphery of a wafer that is subjected to bevel edge processing are applicable to 300 mm wafers. It will be appreciated by those skilled in the art that appropriate adjustments will need to be made to the foregoing ranges for bevel edge processing of wafers having other sizes (e.g., 200 mm or 450 mm wafers).

In the example embodiments shown and described herein, an RF electrode is embedded in the upper PEZ ring because it is more important to have precise control over the etching of the top bevel than it is to have such control over the etching of the bottom bevel. Nevertheless, an RF electrode could be embedded in the lower PEZ ring to provide more precise control over the etching of the bottom bevel. To implement an RF electrode in the lower PEZ ring, however, care must be taken to avoid crosstalk with the main electrode (e.g., bottom electrode 104). One way to avoid such crosstalk would be to provide sufficient spacing between the RF electrode embedded in the lower PEZ ring and the bottom electrode 104, thereby minimizing the capacitive coupling between the bottom electrode and the RF electrode embedded in the lower PEZ ring. Another way would be to supply different RF frequencies to each electrode combined with sufficient mutual RF filtering.

Accordingly, the disclosure of the example embodiments is intended to be illustrative, but not limiting, of the scope of the disclosures, which are set forth in the following claims and their equivalents. Although example embodiments of the disclosures have been described in some detail for purposes of clarity of understanding, it will be apparent that certain changes and modifications can be practiced within the scope of the following claims. In the following claims, elements and/or steps do not imply any particular order of operation, unless explicitly stated in the claims or implicitly required by the disclosure.

What is claimed is:

1. A plasma processing system, comprising:
a chamber;
a bottom electrode disposed in the chamber;
a lower extended electrode disposed around the bottom electrode;
an upper ceramic plate disposed in the chamber, the upper ceramic plate being disposed above the bottom electrode in an opposing relationship with the bottom electrode, such that, when a wafer is present over the bottom electrode, a separation gap is defined between a top surface of the wafer and the upper ceramic plate, wherein the separation gap is less than about 2.0 mm;
an upper extended electrode disposed around the upper ceramic plate;
a lower process exclusion zone ring situated between the lower extended electrode and the bottom electrode;
an upper process exclusion zone ring situated between the upper extended electrode and the upper ceramic plate, the upper process exclusion zone ring having a radio frequency (RF) electrode ring embedded therein;
a first RF generator for generating RF power for the bottom electrode;
a second RF generator for generating RF power for the RF electrode ring embedded in the upper process exclusion zone ring; and
a controller for transmitting processing instructions, the processing instructions including a power setting for the first RF generator and a power setting for the second RF generator.

2. The system of claim 1, wherein the power setting for the second RF generator is lower than the power setting for the first RF generator.

3. The system of claim 2, wherein a cooling plate is disposed over the upper ceramic plate, the upper process exclusion zone ring, and the upper extended electrode, and wherein power generated by the second RF generator is communicated to the embedded RF electrode ring via an RF feed rod that passes through the cooling plate.

4. The system of claim 1, wherein the lower process exclusion zone ring is comprised of an insulative material that electrically separates the bottom electrode and the lower extended electrode.

5. The system of claim 1, wherein the upper process exclusion zone ring is comprised of an insulative material that electrically separates the embedded RF electrode ring from the upper extended electrode.

6. The system of claim 1, wherein the upper process exclusion zone ring has a side surface that defines an outer circumference of the upper process exclusion zone ring and a lower surface that defines a base of the upper process exclusion zone ring, and the RF electrode ring is embedded within the upper process exclusion zone ring so that a side surface of the RF electrode ring is proximate to the side surface of the upper process exclusion zone ring and a bottom surface of the RF electrode ring is proximate to the lower surface of the upper process exclusion zone ring.

7. The system of claim 7, wherein the RF electrode ring is embedded within the upper process exclusion zone ring so that the side surface of the RF electrode ring is within about 1.0 mm of the side surface of the process exclusion ring and the bottom surface of the RF electrode ring is within about 1.0 mm of the lower surface of the upper process exclusion zone ring.

8. A method, comprising:
generating a plasma for bevel edge processing of a wafer when present, the plasma being generated using radio frequency (RF) power delivered to a main electrode supporting the wafer, the RF power being generated by a main RF generator;
providing an upper process exclusion zone ring that defines a physical boundary that establishes an amount of encroachment of the plasma toward a center of the wafer from a bevel edge process region;
applying RF power to an electrode in the upper process exclusion zone ring, the RF power being applied to the electrode in the upper process exclusion zone ring being generated by a secondary RF generator that is separate from the main RF generator; and
controlling the RF power applied to the electrode in the upper process exclusion zone ring to provide an additional barrier to plasma to reduce the amount of encroachment of the plasma toward the center of the wafer from the bevel edge process region, such that an amount of a periphery of the wafer to be bevel edge processed with the generated plasma is reduced.

9. The method of claim 8, wherein the RF power applied to the electrode in the upper process exclusion zone ring is applied at a low frequency.

10. The method of claim 8, wherein the low-frequency RF power applied to the electrode in the upper process exclusion zone ring is applied at a relatively low power level that does not exceed approximately 200 watts, such that the low-frequency RF power produces an electric field in and around the upper process exclusion zone ring that exerts a force against the generated plasma for bevel edge processing that causes the generated plasma to be forced away from the center of the wafer, thereby increasing a plasma sheath, wherein setting increased power settings from zero watts to approximately 200 watts respectively increases an amount of force the electric field exerts against the generated plasma and thereby reduces the amount of the periphery of the wafer that is bevel edge processed with the generated plasma.

11. The method of claim 9, wherein the RF power applied to the electrode in the upper process exclusion zone ring is applied at a low frequency of approximately 400 kHz.

12. The method of claim 8, wherein controlling the RF power applied to the electrode in the upper process exclusion zone ring to provide an additional barrier to plasma to reduce the amount of encroachment of the plasma toward the center of the wafer from the bevel edge process region includes:
identifying a range of RF power levels that cause the amount of encroachment of the plasma toward the center of the wafer from the bevel edge process region to vary between a maximum amount of encroachment and a minimum amount of encroachment; and
adjusting the RF power level to a power level within the range of identified RF power levels to obtain a selected amount of encroachment of the plasma.

13. The method of claim 12, wherein the identified RF power levels are in the range from zero watts to approximately 200 watts, with the RF power level of zero watts corresponding to a maximum amount of encroachment and the RF power lever of approximately 200 watts corresponding to a minimum level of encroachment, and RF power level is adjusted to a power level between zero watts and approximately 200 watts to obtain the selected amount of encroachment of the plasma.

14. The method of claim 13, wherein the RF power is applied at a low frequency of approximately 400 kHz

15. A plasma processing system, comprising:
a chamber;
a bottom electrode disposed in the chamber;
a lower extended electrode disposed around the bottom electrode;
an upper ceramic plate disposed in the chamber, the upper ceramic plate being disposed above the bottom electrode in an opposing relationship with the bottom electrode, such that a separation gap is defined between a top surface of a wafer, when present over the bottom electrode, and the upper ceramic plate, wherein the separation gap is less than about 2.0 mm;
an upper extended electrode disposed around the upper ceramic plate;
a lower process exclusion zone ring situated between the lower extended electrode and the bottom electrode, the lower process exclusion zone ring being comprised of an insulative material that electrically separates the bottom electrode from the lower extended electrode;
an upper process exclusion zone ring situated between the upper extended electrode and the upper ceramic plate, the upper process exclusion zone ring having a radio frequency (RF) electrode ring embedded therein, and the upper process exclusion zone ring being comprised of an insulative material that electrically separates the embedded RF electrode ring from the upper extended electrode;
an RF generator for generating RF power for the bottom electrode, the RF generator for generating the RF power for the bottom electrode having a matching circuit associated therewith;
an encroachment power module, the encroachment power module including an RF generator for generating RF power for the RF electrode ring embedded in the upper process exclusion zone ring and a matching circuit associated with the RF generator for generating the RF power for the embedded RF electrode ring; and
a controller for transmitting processing instructions, the processing instructions including general etch settings and encroachment control settings.

16. The system of claim 14, wherein the encroachment control settings include a power setting for the RF generator included in the encroachment power module.

17. The system of claim 16, wherein the power setting for RF generator included in the encroachment power module is lower than a power setting for the RF generator for generating RF power for the bottom electrode.

18. The system of claim 16, wherein the power setting for the RF generator included in the encroachment power module does not exceed approximately 200 watts.

19. The system of claim 15, wherein the RF power generated by the RF generator included in the encroachment power module is low frequency power.

20. The system of claim 19, wherein the low-frequency RF power has a frequency of approximately 400 kHz.
